(19) United States
(12) Patent Application Publication
(10) Pub. No.: US 2011/0181333 A1
(43) Pub. Date: Jul. 28, 2011

(54) STACKED TRANSISTOR DELAY CIRCUIT AND METHOD OF OPERATION

(76) Inventor: RAVINDRARAJ RAMARAJU, Round Rock, TX (US)

(21) Appl. No.: 12/695,441

(22) Filed: Jan. 28, 2010

(51) Int. Cl. H03H 11/26

(52) U.S. Cl. 327/272

(57) ABSTRACT

A delay circuit and method of operation has a plurality of series-connected stages including a first stage and a last stage that provides the delayed signal. Each of the series-connected stages has a plurality of series-connected transistors having an outermost transistor and an innermost transistor and one or more or none of a plurality of intervening transistors. Each of the plurality of series-connected transistors is connected in series to a respective different load stack. An input signal that is coupled to the first stage is propagated repeatedly between the first stage, intervening stages if any, and a last stage. The first stage has a signal input, one or more feedback inputs, and at least two output terminals.

### BACKGROUND

1. Field

This disclosure relates generally to electrical circuits, and more specifically, to a stacked transistor delay circuit and method of operation.

2. Related Art

Delay circuits are used in electrical circuits for a variety of reasons. For example, one or more inverter circuits connected in series are commonly used to provide precise timing control, correct clock skew, and to adjust hold times in data processors and memories. A conventional CMOS (complementary metal-oxide semiconductor) inverter includes a P-channel transistor and an N-channel transistor connected in series. The conventional CMOS inverter can use considerable power when switching and can have a significant leakage current when not switching. A system having a large number of inverters may have significantly increased power consumption. If the system is in a battery powered application, battery life can be adversely affected. Also, a series of CMOS inverters are susceptible to glitches. A glitch inserted into a series of common CMOS inverters may propagate to the output causing logic errors.

Therefore, what is needed is a delay circuit that solves the above problems.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in schematic diagram form, a delay circuit in accordance with an embodiment.

FIG. 2 illustrates, in schematic diagram form, a delay circuit in accordance with another embodiment.

FIG. 3 illustrates a flow chart for a method of operating the delay circuits of FIG. 1 and FIG. 2.

### DETAILED DESCRIPTION

Generally, there is provided, a delay circuit having a plurality of stages. Each stage includes a transistor stack. The stages are connected together in series. In operation, the outermost transistors of each stack are switched on or off in a first to last sequence in response to an input logic signal. The outermost transistors are the transistors closest to the power supply terminals. A feedback signal from the last of the outermost transistors is used to begin switching the next outermost transistors in a first to last sequence, and so forth, until all of the transistors are switched and a delayed output logic signal is provided. In the following illustrated embodiments, the stages can have any even number of transistors and there can be any even number of stages. For example, one described embodiment includes two stages with four transistors per stage. Another described embodiment includes four stages with eight transistors per stage. The amount of delay can be more finely tuned by changing transistor gate widths.

The disclosed delay circuit has low leakage current and is therefore very power efficient. Also, the delay circuit will automatically prevent input glitches from propagating to the output. In addition, the delay circuit can provide a relatively large amount of delay while still being finely tunable.

In one aspect, there is provided, a delay circuit, comprising: a first stage having a first plurality of transistors coupled in series with a first load of stacked devices, the first stage having a first input terminal for receiving an input signal which is to be delayed, a second input terminal, and a plurality of output terminals; and a second stage having a second plurality of transistors coupled in series with a second load of stacked devices, the second stage having a first input terminal coupled to a first output terminal of the plurality of outputs of the first stage, a second input terminal coupled to a second output terminal of the plurality of outputs of the first stage, a first output terminal coupled to the second input terminal of the first stage and an output terminal for providing a delayed signal of the input signal.

The first plurality of transistors of the first stage may comprise: a first transistor of a first conductivity type having a first current electrode coupled to a first power supply voltage terminal, a control electrode coupled to the first input terminal of the first stage and a second current electrode coupled to the first output terminal of the first stage; a second transistor of the first conductivity type having a first current electrode coupled to the second current electrode of the first transistor, a control electrode coupled to the second input terminal of the first stage, and a second current electrode coupled to the second output terminal of the first stage; and wherein the first load of stacked devices of the first stage may further comprise: a third transistor of a second conductivity type that is opposite the first conductivity type having a first current electrode coupled to second current electrode of the second transistor at the second output terminal of the first stage, a control electrode coupled to the control electrode of the second transistor at the second input terminal of the first stage, and a second current electrode; and a fourth transistor of the second conductivity type having a first current electrode coupled to the second current electrode of the third transistor, a control electrode coupled to the control electrode of the first transistor at the first input terminal of the first stage, and a second current electrode coupled to a second power supply voltage terminal. The second plurality of transistors of the second stage may comprise: a fifth transistor of a first conductivity type having a first current electrode coupled to the first power supply voltage terminal, a control electrode coupled to the first output terminal of the first stage and a second current electrode coupled to the first output terminal of the second stage; a sixth transistor of the first conductivity type having a first current electrode coupled to the second current electrode of the fifth transistor, a control electrode coupled to the second output terminal of the first stage, and a second current electrode coupled to the second output terminal of the second stage; and wherein the second load of stacked devices of the second stage may further comprise: a seventh transistor of the second conductivity type having a first current electrode coupled to second current electrode of the sixth transistor at the second output terminal of the second stage, a control electrode coupled to the control electrode of the sixth transistor at the second output terminal of the first stage, and a second current electrode; and an eighth transistor of the second conductivity type having a first current electrode coupled to the second current electrode of the seventh transistor, a control electrode coupled to the control electrode of the fifth transistor at the first input terminal of the second stage, and a second current electrode coupled to the second power supply voltage terminal. The first transistor may have an effective channel width that is equal to an effective channel width of the second transistor and a first amount of delay added to the input signal at the first output terminal of the first stage is different from a second amount of delay added to the input signal at the second output terminal of the first stage. Each of the plurality of output terminals may provide a delayed form of the input signal at a different point in time.

In another aspect, there is provided, a method comprising: providing a plurality of series-coupled stages each having a plurality of series-coupled transistors that are coupled in series with a respective one of a plurality of load stacks, each of the series-coupled transistors comprising an outermost transistor and an inner most transistor with or without any intervening pairs of series-connected transistors; inputting a signal to the outermost transistor of a first of the plurality of series-coupled transistors of a first stage and propagating the signal in a predetermined sequence to all remaining stages; feeding back the signal from a last outermost transistor of a last stage to a first transistor of next outermost transistors and propagating the signal in the predetermined sequence; if additional transistors in the plurality of series-coupled transistors exist, continue propagating the signal through any additional transistors in the predetermined sequence until outputting the signal at an output of a last stage of the series-coupled stages as a delayed signal; and if no additional transistors in the plurality of series-coupled transistors exist, outputting the delayed signal upon completion of propagating the delayed signal to a last transistor of the predetermined sequence. The method may further comprise coupling a second plurality of transistors in series to implement each of the load stacks. The method may further comprise forming a same number of transistors for the plurality of series-coupled transistors and second plurality of transistors in each stage. The method may further comprise providing an even numbered plurality of series-coupled stages. The method may further comprise providing four series-coupled stages as the plurality of series-coupled stages, each respective series-coupled stage comprising an input terminal, three feedback input terminals and four output terminals and comprising four series-connected transistors of a first conductivity type, and each respective load stack comprising load inputs respectively connected to the input terminal and three feedback input terminals, each respective load stack comprising four series-connected transistors of a second conductivity type opposite the first conductivity type. The method may further comprise providing two series-coupled stages as the plurality of series-coupled stages. The method may further comprise: implementing each of the two series-coupled stages with two series-connected P-channel transistors wherein a first P-channel transistor of a first stage is the outermost transistor and has a gate for receiving the signal, and a gate of a second P-channel transistor receives the signal that is fed back from the last outermost transistor, a first output of the first stage being a first node between the first P-channel transistor and the second P-channel transistor; and implementing each load stack with two series-coupled N-channel transistors wherein a gate of a first N-channel transistor is coupled to the signal and a gate of a second N-channel transistor is coupled to the signal that is fed back, a second node between the load stack and second P-channel transistor being a first output of the first stage and the first and second P-channel transistors being connected to the first node. The method may further comprise repeating propagation of the signal between a first stage and a last stage of the series-coupled stages and delaying the signal within the first stage with differing amounts of delay by implementing the plurality of series-coupled transistors of the first stage with a same transistor channel width to create differing amounts of delay. The method may further comprise repeating propagation of the signal between the first stage and the last stage by repeating the signal through the first stage twice. The method may further comprise repeating propagation of the signal between the first stage and the last stage by repeating the signal through the first stage four times.

In yet another aspect, there is provided, a delay circuit for receiving a signal and providing a delayed signal, comprising a plurality of series-connected stages including a first stage and a last stage that provides the delayed signal, each of the series-connected stages comprising a plurality of series-connected transistors comprising an outermost transistor and an innermost transistor and any one of none to a plurality of intervening transistors, each of the plurality of series-connected transistors connected in series to a respective different load stack, wherein a signal coupled to the first stage is propagated repeatedly between the first stage and last stage, the first stage having a signal input, one or more feedback inputs, and at least two output terminals. The signal may be delayed within the first stage with differing amounts of delay in differing repeated signal propagations through the first stage by implementing the plurality of series-coupled transistors of the first stage with a same transistor channel width to create differing amounts of delay. The outermost transistor is connected directly to a power supply voltage terminal and the innermost transistor is a last of the series-connected transistors of a respective stage to receive a feedback signal, all of the series-connected transistors in the respective stage except the outermost transistor being connected to two output terminals of the respective stage. The first stage may comprise: a first P-channel transistor having a first current electrode coupled to a first power supply voltage terminal, a control terminal for receiving the signal, and a second current electrode for providing a first output of the first stage; a second P-channel transistor having a first current electrode coupled to the second current electrode of the first P-channel transistor, a control terminal for receiving a feedback signal, and a second current electrode for providing a second output of the first stage; a first N-channel transistor having a first current electrode coupled to the second current electrode of the second P-channel transistor, a control terminal for receiving the feedback signal, and a second current electrode coupled to the first output of the first stage; and a second N-channel transistor having a first current electrode coupled to the second current electrode of the first N-channel transistor, a control terminal for receiving the signal, and a second current electrode coupled to a second power supply voltage terminal; and wherein the second stage may comprise: a third P-channel transistor having a first current electrode coupled to the first power supply voltage terminal, a control electrode coupled to the first output of the first stage, and a second current electrode for providing a first output of the second stage; a fourth P-channel transistor having a first current electrode coupled to the second current electrode of the third P-channel transistor, a control electrode coupled to the second output of the first stage, and a second current electrode for providing a second output of the second stage which provides the delayed signal; a third N-channel transistor having a first current electrode coupled to the second current electrode of the fourth P-channel transistor, a control electrode coupled to the second output of the first stage, and a second current electrode coupled to the second current electrode of the third P-channel transistor for providing the first output of the second stage; and a fourth N-channel transistor having a first current electrode coupled to the second current electrode of the third N-channel transistor, a control electrode coupled to the first output of the first stage, and a second current electrode coupled to the second power supply voltage terminal. The at least two output terminals may provide a delayed form of the signal input at a different point in time.

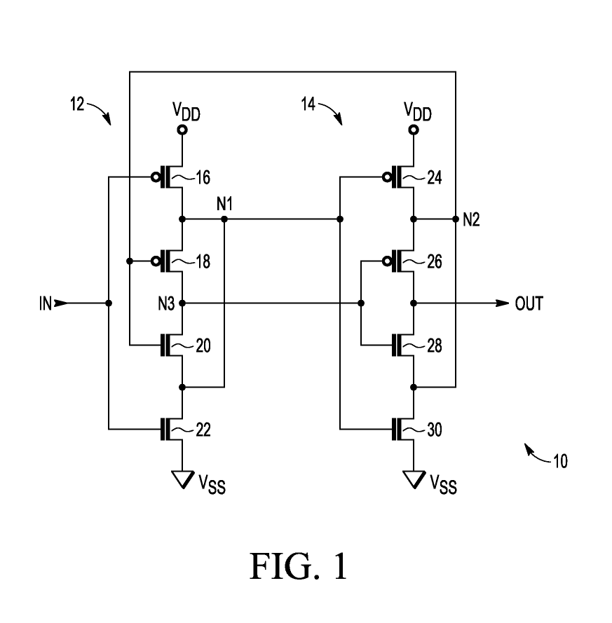

FIG. 1 illustrates, in schematic diagram form, a delay circuit 10 in accordance with an embodiment. Delay circuit 10 includes stages 12 and 14. Stage 12 is a transistor stack including P-channel transistors 16 and 18 and N-channel transistors 20 and 22. Stage 14 is a transistor stack including P-channel transistors 24 and 26 and N-channel transistors 28 and 30. Generally, a transistor stack is a plurality of transistors coupled together in series between power supply terminals. In one embodiment, the transistors are implemented on an integrated circuit using a conventional CMOS manufacturing process. In other embodiments, different manufacturing processes and different transistors with different conductivity types can be used.

In stage 12, P-channel transistor 16 has a first current electrode connected to a power supply voltage labeled “VDD”, a control electrode coupled to receive an input signal labeled “IN”, and a second current electrode coupled to a node labeled “N1”. P-channel transistor 18 has a first current electrode connected to the second current electrode of P-channel transistor 16 at node N1, a control electrode coupled to a node labeled “N2”, and a second current electrode coupled to a node labeled “N3”. N-channel transistor 20 has a first current electrode connected to the second current electrode of transistor 18 at node N3, a control electrode connected to the control electrode of transistor 18 at node N2, and a second current electrode connected to the second current electrode of transistor 16 at node N1. N-channel transistor 22 has a first current electrode connected to the second current electrode of transistor 20 at node N1, a control electrode connected to the control electrode of transistor 16 for receiving input signal IN, and a second current electrode connected to a power supply voltage terminal labeled VSS. In the illustrated embodiment, power supply voltage VDD is a positive power supply voltage and VSS is at ground potential. In other embodiments, different power supply voltages can be used. Also, in the illustrated embodiment, the first and second current electrodes are drain/source terminals, and the control electrodes are gate terminals. In other embodiments, the transistor terminals may be different.

In stage 14, P-channel transistor 24 has a first current electrode connected to VDD, a control electrode connected to the second current electrode of transistor 16 at node N1, and a second current electrode connected to the control electrodes of transistors 18 and 20. P-channel transistor 26 has a first current electrode connected to the second current electrode of transistor 24 at node N2, a control electrode connected to the second current electrode of transistor 18 at node N3, and a second current electrode connected to an output terminal labeled “OUT”. N-channel transistor 28 has a first current electrode connected to the second current electrode of transistor 26 at output terminal OUT, a control electrode connected to the control electrode of transistor 26 at node N3, and a second current electrode connected to the control terminals of transistors 18 and 20 at node N2. N-channel transistor 30 has a first current electrode connected to the second current electrode of transistor 28 at node N2, a control electrode connected the control electrode of transistor 24 at node N3, and a second current electrode connected to power supply voltage terminal VSS. Node N1 functions as an output node for transistors 16 and 22, and as an input terminal for transistors 24 and 30. Node N2 functions as an output terminal for transistors 24 and 30, and as an input terminal for transistors 18 and 20. Node N3 functions as an output terminal for transistors 18 and 20, and as an input terminal for transistors 26 and 28. Each of nodes N1 and N2 provide a delayed form of the input signal.

In operation, delay circuit 10 provides a delayed output logic signal OUT corresponding to an input logic signal IN. In response to receiving input logic signal IN, the outermost transistors of each stage are switched. In the embodiment of FIG. 1, the outermost transistors are transistors 16, 22, 24, and 30. The signal from the last stage 14 is fed back to the next outermost transistors of the first stage 12. In FIG. 1, the next outermost transistors are also the innermost transistors because there are only four transistors in a stage. The signal propagates through the stages until the last transistor is switched. If there are more transistors in the stages, then the signal is fed back to the next transistors until all of the transistors in each stage have been switched. The output logic signal OUT, corresponding the input logic signal IN, is outputted having a predetermined delay that is the sum of all of the gate delays in the circuit. In the circuit of FIG. 1, the number of gate delays is equal to four because two transistors are switched substantially simultaneously each time the signal propagates between stages. For example, transistor 22 is switched at the same time as transistor 16. The amount of delay provided by delay circuit 10 can be adjusted by changing the number of transistors in a stage, or by changing the number of stages. An odd number of stages may be used if an inverter is inserted in each feedback path. The delay can also be changed by, for example, changing the relative sizes of the transistors. Like a conventional CMOS inverter, each stage provides a signal inversion. The amount of delay may be further adjusted by changing the gate widths of the transistors or by providing the output signal from one of the other nodes. The delay may be used anywhere it is necessary to delay a signal. For example, delay may be added to a clock signal to synchronize the clock signal across time domains in a data processing system. Also, delay may be used in a memory, such as for example, an SRAM (static random access memory) or DRAM (dynamic random access memory), to coordinate various operations of the memory.

The operation of delay circuit 10 will now be described in more detail. An input signal is provided to the first outermost transistors 16 and 22. If input logic signal IN has a logic low state (logic zero), P-channel transistor 16 will be switched on (conductive) and N-channel transistor 22 will be switched off (non-conductive). Node N1 will be pulled to about VDD (logic high) by the conductive P-channel transistor 16. The logic high at node N1 will cause P-channel transistor 24 to be switched off (non-conductive) and N-channel transistor 30 will be switched on (conductive). The voltage at node N2 will be pulled to a logic low by transistor 30. The logic low voltage of node N2 will be fed back to the first next outermost transistors of stage 12, that is, P-channel transistor 18 and N-channel transistor 20. Note that the next outermost transistors 18, 20, 26, and 28 in FIG. 1 are also the innermost transistors. The logic low voltage from node N2 will cause P-channel transistor 18 to be conductive and N-channel transistor 20 to be substantially non-conductive. Node N3 will be pulled to a logic high voltage. The logic high at node N3 will be provided to the gates (control electrodes) of P-channel transistor 26 and N-channel transistor 28. P-channel transistor 26 will be switched off (non-conductive), and N-channel transistor 28 will be switched on (conductive). Therefore, transistors 28 and 30 are both conductive, transistors 24 and 26 are both non-conductive and a logic low output signal OUT is provided.

Conversely, if an input logic signal IN is provided that has a logic high state (logic one), P-channel transistor 16 will be switched off (non-conductive) and N-channel transistor 22 will be switched on (conductive). Node N1 will be pulled low to about VSS (logic low) by the conductive N-channel transistor 22. The logic low at node N1 will cause P-channel transistor 24 to be switched on (conductive) and N-channel transistor 30 will be switched off (non-conductive). The voltage at node N2 will be pulled to a logic high by transistor 24. The logic high voltage of node N2 will be fed back to the next outermost transistors of stage 12, that is, P-channel transistor 18 and N-channel transistor 20. The logic high voltage from node N2 will cause P-channel transistor 18 to be non-conductive and N-channel transistor 20 to be conductive. Node N3 will be pulled to a logic low voltage. The logic low at node N3 will be provided to the gates (control electrodes) of P-channel transistor 26 and N-channel transistor 28. P-channel transistor 26 will be switched on (conductive), and N-channel transistor 28 will be non-conductive. Therefore, transistors 24 and 26 are both conductive, transistors 28 and 30 are non-conductive, and a logic high output signal OUT is provided.

When switching from one logic state to another logic stage, delay circuit 10 provides four gate delays. A gate delay is the time it takes a transistor to switch on or to switch off. The four gate delays are generally equivalent to four gate delays provided by four series-connected CMOS inverters, except that a gate delay of delay circuit 10 may be longer than a gate delay of the conventional two transistor inverter having substantially equal transistor sizes (gate length and width). This is because the stacked transistors of each stage will switch more slowly because of the additional intervening transistors. For example, outermost transistors 16 and 24 may have effective channel widths that are equal to effective channel widths of innermost transistors 18 and 26. A first amount of delay added to the signal at node N1 of the first stage by outermost transistor 16 may be different from a second amount of delay added to the signal at node N3 by innermost transistor 18. In other words, the signal may be delayed within stage 12 with differing amounts of delay in differing repeated signal propagations through stage 12 by implementing series-connected transistors 16 and 18 with a same transistor channel width to create differing amounts of delay. Note that in another embodiment, half of the transistors, either the top half or the bottom half, in each stack may be replaced with active or passive loads, so that no feedback signal is provided to that half. For example, transistors 20, 22, 28, and 30 may be replaced with a stack of either diode-connected transistors or resistors.

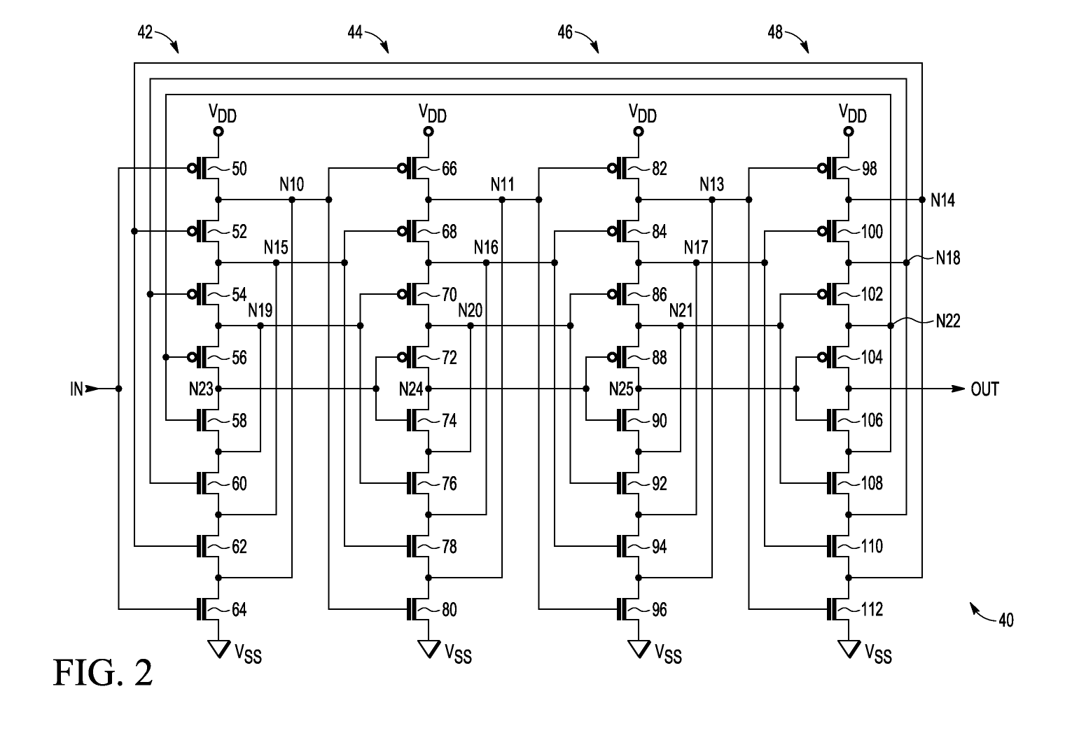

FIG. 2 illustrates, in schematic diagram form, a delay circuit 40 in accordance with another embodiment. Delay circuit 40 includes four stages 42, 44, 46, and 48. Each stage includes a stack of 8 series-connected transistors. Stage 42 includes P-channel transistors 50, 52, 54, and 56, and N-channel transistors 58, 60, 62, and 64. Stage 44 includes P-channel transistors 66, 68, 70, and 72, and N-channel transistors 74, 76, 78, and 80. Stage 46 includes P-channel transistors 82, 84, 86, and 88, and N-channel transistors 90, 92, 94, and 96. Stage 48 includes P-channel transistors 98, 100, 102, and 104, and N-channel transistors 106, 108, 110, and 112. As can be seen, delay circuit 40 includes four stages and eight transistors per stage. In another embodiment, there can be more or fewer stages. However, in another embodiment, an odd number of stages can be used if additional logic is included to ensure the correct logic state of the feedback signal. For example, an odd number of stages can be used if an inverter is included in each feedback path (not shown). In addition, as discussed above, in another embodiment the bottom half transistors of each stack (for example, the N-channel transistors) can be replaced with stacked active or passive loads that do not receive the feedback signals. Further, in another embodiment, the top half of each stack (for example, the P-channel transistors) can be replaced with stacked active or passive loads that do not receive the feedback signals. In one embodiment, a stacked active load comprises a plurality of diode-connected transistors coupled together in series. In another embodiment, a stacked passive load comprises a plurality of resistors coupled together in series. An advantage of using the stacked passive loads, either in the top half or the bottom half of the delay circuit is reduced complexity at the cost of higher power consumption.

In operation, delay circuit 40 functions the same as delay circuit 10, except that there are more transistors to switch. In response to an input signal IN, the outermost P-channel transistors 50, 66, 82, and 98 switch in a predetermined sequence simultaneously with N-channel transistors 64, 80, 96, and 112. Generally, the switching sequence is in the order of first-to-last. For example, the first outermost P-channel transistor 50 and N-channel transistor 64 switches a logic state of node N10. The signal propagates through nodes N11, N13, and N14 in the first-to-last sequence. The signal IN is fed back to the gates of the first, next outermost transistors 52 and 62. The input signal IN propagates through nodes N15, N16, N17, and N18, and then fed back to the gates of the first transistors of the next outermost transistors 54 and 60. The signal then propagates through nodes N19, N20, N21, and N22, and is fed back to the gates of the first innermost transistors 56 and 58. The signal propagates through nodes N23, N24, N25, and is output as a delayed signal OUT.

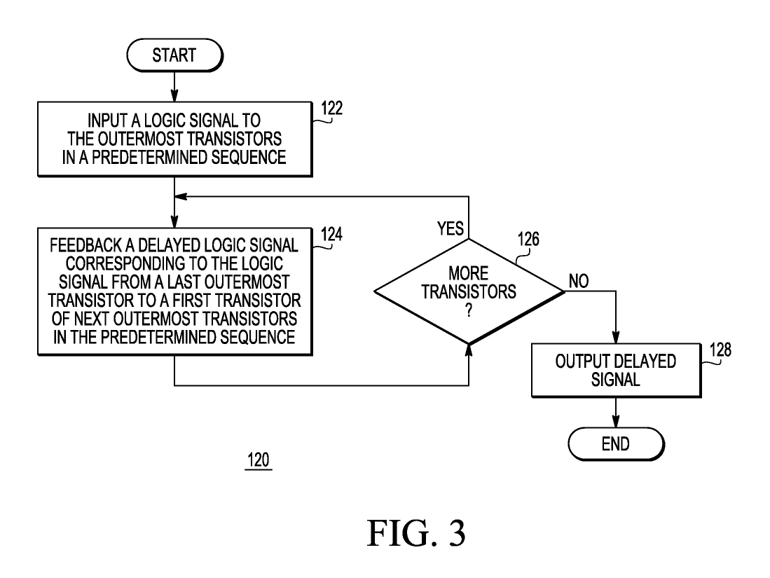

FIG. 3 illustrates a flow chart for a method 120 of operating the delay circuits of FIG. 1 and FIG. 2. Method 120 begins at step 122. At step 122, a logic signal IN is input to a delay circuit, such as for example, delay circuit 10 of FIG. 1 or delay circuit 40 of FIG. 2. The input signal IN is provided to the first outermost transistors of a first stack, or stage, of transistors. For example, the first outermost transistors of the first stage 12 of delay circuit 10 are transistors 16 and 22. The first outermost transistors of the first stage 42 of delay circuit 40 are transistors 50 and 64. The input signal IN is provided to each of the outermost transistors of each of the following stages in a predetermined sequence. In one embodiment, the predetermined sequence is from first-to-last. At step 124, the signal is fed back from the last outermost transistor of the last stage to a first transistor of next outermost transistors of the first stage (see FIG. 1 or FIG. 2) and propagates through the series of stages to the last stage. At decision step 126, it is determined if there are more transistors to switch. If there are more transistors to switch, for example, additional next outermost transistors or innermost transistors, the YES path is taken from step 126 back to step 124 and the signal is fed back and circulated to the next outermost transistors from the first stage to the last stage. Steps 126 and 124 are repeated until all of the innermost transistors are switched. When there are no more transistors to switch, the NO path is taken from step 126 to step 128. At step 128, the delayed signal is output as delayed output signal OUT.

The amount of delay provided to the output signal OUT is determined by the number of transistors in the delay circuit as well as the gate widths of the transistors. Delay circuits 10 and 40 can be made to provide more delay than an equivalent sized inverter chain because the transistors in the transistor stacks will switch more slowly given the same transistor size. This is because the effective gate widths of the transistors decreases the closer the transistor placement is to the center of the stack. An advantage of the transistor stacks is the elimination of both leakage current when the delay circuit is static and switching current when the delay circuit is operating. Also, a signal glitch introduced at the input will be automatically filtered out as the signal propagates repeatedly through the stages. In addition, the amount of delay can be changed by changing the number of stages or the number of transistors in each stage. The amount of delay can be finely tuned by changing the transistor widths.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A delay circuit, comprising:
a first stage having a first plurality of transistors coupled in series with a first load of stacked devices, the first stage having a first input terminal for receiving an input signal which is to be delayed, a plurality of input terminals, and a plurality of output terminals;
a second stage having a second plurality of transistors coupled in series with a second load of stacked devices, the second stage having a plurality of input terminals coupled to the plurality of output terminals of the first stage, and a plurality of output terminals; and
a third stage having a third plurality of transistors coupled in series with a third load of stacked devices, the third stage having a plurality of input terminals coupled to the plurality of output terminals of the second stage, and a plurality of output terminals coupled to the plurality input terminals of the first stage, and an output terminal for providing a delayed signal of the input signal.

2. The delay circuit of claim 1 wherein the first plurality of transistors of the first stage comprises:
a first transistor of a first conductivity type having a first current electrode coupled to a first power supply voltage terminal, a control electrode coupled to the first input terminal of the first stage and a second current electrode coupled to a first output terminal of the first stage;
a second transistor of the first conductivity type having a first current electrode coupled to the second current electrode of the first transistor, a control electrode coupled to a second input terminal of the first stage, and a second current electrode coupled to a second output terminal of the first stage; and
wherein the first load of stacked devices of the first stage further comprises:
a third transistor of a second conductivity type that is opposite the first conductivity type having a first current electrode coupled to second current electrode of the second transistor at the second output terminal of the first stage, a control electrode coupled to the control electrode of the second transistor at the second input terminal of the first stage, and a second current electrode; and
a fourth transistor of the second conductivity type having a first current electrode coupled to the second current electrode of the third transistor, a control electrode coupled to the control electrode of the first transistor at the first input terminal of the first stage, and a second current electrode coupled to a second power supply voltage terminal.

3. The delay circuit of claim 2 wherein the second plurality of transistors of the second stage comprises:
a fifth transistor of a first conductivity type having a first current electrode coupled to the first power supply voltage terminal, a control electrode coupled to the first output terminal of the first stage and a second current electrode coupled to a first output terminal of the second stage;
a sixth transistor of the first conductivity type having a first current electrode coupled to the second current electrode of the fifth transistor, a control electrode coupled to the second output terminal of the first stage, and a second current electrode coupled to a second output terminal of the second stage; and
wherein the second load of stacked devices of the second stage further comprises:
a seventh transistor of the second conductivity type having a first current electrode coupled to second current electrode of the sixth transistor at the second output terminal of the second stage, a control electrode coupled to the control electrode of the sixth transistor at the second output terminal of the first stage, and a second current electrode; and
an eighth transistor of the second conductivity type having a first current electrode coupled to the second current electrode of the seventh transistor, a control electrode coupled to the control electrode of the fifth transistor at the first input terminal of the second stage, and a second current electrode coupled to the second power supply voltage terminal.

4. The delay circuit of claim 2 wherein the first transistor has an effective channel width that is equal to an effective channel width of the second transistor and a first amount of delay added to the input signal at the first output terminal of the first stage is different from a second amount of delay added to the input signal at the second output terminal of the first stage.

5. The delay circuit of claim 1 wherein each of the plurality of output terminals of the third stage provides a delayed form of the input signal at a different point in time.

6. A method comprising:
providing four series-coupled stages, each respective series-coupled stage comprising an input terminal, three feedback input terminals and four output terminals and comprising four series-connected transistors of a first conductivity type, each of the four series-coupled stages comprising a load stack, each respective load stack comprising load inputs respectively connected to the input terminal and three feedback input terminals, each respective load stack comprising four series-connected transistors of a second conductivity type opposite the first conductivity type;
inputting a signal to the outermost transistor of a first of the four series-connected transistors of a first stage and propagating the signal in a predetermined sequence to all remaining stages; and
feeding back the signal from a last outermost transistor of a last stage to a first transistor of next outermost transistors and propagating the signal in the predetermined sequence until outputting the signal at an output of a last stage of the four series-connected stages as a delayed signal.

7-15. (canceled)

16. A delay circuit for receiving a signal and providing a delayed signal, comprising:
a plurality of series-connected stages including a first stage, an intermediate stage, and a last stage that provides the delayed signal, each of the series-connected stages comprising a plurality of series-connected transistors comprising an outermost transistor and an innermost transistor and any one of none to a plurality of intervening transistors, each of the plurality of series-connected transistors connected in series to a respective different load stack, wherein a signal coupled to the first stage is propagated repeatedly between the first stage, the intermediate stage, and last stage for a plurality of iterations, the first stage having a signal input, one or more feedback inputs, and at least two output terminals, the last stage having a signal output, and wherein the delayed signal is only provided at the signal output after the plurality of iterations are complete.

17. The delay circuit of claim 16 wherein the signal is delayed within the first stage with differing amounts of delay in differing repeated signal propagations through the first stage by implementing the plurality of series-coupled transistors of the first stage with a same transistor channel width to create differing amounts of delay.

18. The delay circuit of claim 16 wherein the outermost transistor is connected directly to a power supply voltage terminal and the innermost transistor is a last of the series-connected transistors of a respective stage to receive a feedback signal, all of the series-connected transistors in the respective stage except the outermost transistor being connected to two output terminals of the respective stage.

19. The delay circuit of claim 16 wherein the first stage comprises:
a first P-channel transistor having a first current electrode coupled to a first power supply voltage terminal, a control terminal for receiving the signal, and a second current electrode for providing a first output of the first stage;
a second P-channel transistor having a first current electrode coupled to the second current electrode of the first P-channel transistor, a control terminal for receiving a feedback signal, and a second current electrode for providing a second output of the first stage;
a first N-channel transistor having a first current electrode coupled to the second current electrode of the second P-channel transistor, a control terminal for receiving the feedback signal, and a second current electrode coupled to the first output of the first stage; and
a second N-channel transistor having a first current electrode coupled to the second current electrode of the first N-channel transistor, a control terminal for receiving the signal, and a second current electrode coupled to a second power supply voltage terminal; and
wherein the intermediate stage comprises:
a third P-channel transistor having a first current electrode coupled to the first power supply voltage terminal, a control electrode coupled to the first output of the first stage, and a second current electrode for providing a first output of the intermediate stage;
a fourth P-channel transistor having a first current electrode coupled to the second current electrode of the third P-channel transistor, a control electrode coupled to the second output of the first stage, and a second current electrode for providing a second output;
a third N-channel transistor having a first current electrode coupled to the second current electrode of the fourth P-channel transistor, a control electrode coupled to the second output of the first stage, and a second current electrode coupled to the second current electrode of the third P-channel transistor for providing the first output of the intermediate stage; and
a fourth N-channel transistor having a first current electrode coupled to the second current electrode of the third N-channel transistor, a control electrode coupled to the first output of the first stage, and a second current electrode coupled to the second power supply voltage terminal.

20. The delay circuit of claim 16 wherein the at least two output terminals provide a delayed form of the signal input at a different point in time.
